(19) United States
(12) Patent Application Publication
(10) Pub. No.: US 2025/0199179 A1
(43) Pub. Date: Jun. 19, 2025

(54) LIGHT EMITTING DEVICE AND DISTANCE MEASUREMENT APPARATUS

(71) Applicant: FUJIFILM Business Innovation Corp., Tokyo (JP)

(72) Inventors: Tomoaki SAKITA, Kanagawa (JP); Kei TAKEYAMA, Kanagawa (JP); Yoshihiro YAMAMOTO, Kanagawa (JP); Daisuke IGUCHI, Kanagawa (JP); Junichiro HAYAKAWA, Kanagawa (JP)

(73) Assignee: FUJIFILM Business Innovation Corp., Tokyo (JP)

(21) Appl. No.: 18/673,350

(22) Filed: May 24, 2024

(30) Foreign Application Priority Data
Dec. 13, 2023 (JP) 2023-210100

(51) Int. Cl. G01S 17/48; G01S 7/48; G01S 7/481

(52) U.S. Cl. CPC G01S 17/48; G01S 7/4808; G01S 7/4815

(57) ABSTRACT

A light emitting device includes a light emitting element array in which plural light emitting elements are arranged such that a length in one direction is w, the light emitting element array being a first light emitting element array and a second light emitting element array that are parallel to each other in the one direction, a first optical system that refracts light emitted from the first light emitting element array, and a second optical system that refracts light emitted from the second light emitting element array such that an irradiation region of the second light emitting element array is parallel to an irradiation region of the first light emitting element array in the one direction, in which a distance between an optical axis of the first optical system and a center of the first light emitting element array and a distance between an optical axis of the second optical system and a center of the second light emitting element array in the one direction are w/4 or more and w/2 or less.

### CROSS-REFERENCE TO RELATED APPLICATIONS

This application is based on and claims priority under 35 USC 119 from Japanese Patent Application No. 2023-210100 filed Dec. 13, 2023.

### BACKGROUND

### (i) Technical Field

The present invention relates to a light emitting device and a distance measurement apparatus.

### (ii) Related Art

JP2020-191268A discloses a vehicular lamp that forms a predetermined light distribution including a plurality of light source images disposed in a horizontal direction, in which at least one light source is disposed in a state of being shifted with respect to an optical axis of a corresponding projection optical system, so that the light source images can be disposed in a state of being adjacent to each other without a gap even in a case where a disposition interval of the light sources is increased.

### SUMMARY

In JP2020-191268A, a size of the light source is assumed to be sufficiently small compared to a lens, but depending on the light source to be selected such as a case where the light intensity of the light source is intended to be increased, the light source may occupy a large area in the entire light emitting device. In that case, the amount of shift between the light source and the optical system is greatly changed as compared with a case where the light source is sufficiently small compared to the optical system.

Aspects of non-limiting embodiments of the present disclosure relate to a light emitting device and a distance measurement apparatus that suppress formation of a non-irradiation portion between irradiation regions parallel to each other by disposing a light emitting element array and an optical system.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device including a light emitting element array in which a plurality of light emitting elements are arranged such that a length in one direction is w, the light emitting element array being a first light emitting element array and a second light emitting element array that are parallel to each other in the one direction, a first optical system that refracts light emitted from the first light emitting element array, and a second optical system that refracts light emitted from the second light emitting element array such that an irradiation region of the second light emitting element array is parallel to an irradiation region of the first light emitting element array in the one direction, in which a distance between an optical axis of the first optical system and a center of the first light emitting element array and a distance between an optical axis of the second optical system and a center of the second light emitting element array in the one direction are w/4 or more and w/2 or less.

### BRIEF DESCRIPTION OF THE DRAWINGS

Exemplary embodiment(s) of the present invention will be described in detail based on the following figures, wherein:

FIG. 1 is a block diagram showing an example of a schematic configuration of a distance measurement apparatus to which the present exemplary embodiment is applied;

FIG. 2 is a diagram showing a light emitting unit according to the present exemplary embodiment and an irradiation surface that is irradiated with light emitted from the light emitting unit;

FIG. 3 is a diagram describing configurations of light sources of the light emitting unit;

FIG. 4 is a diagram describing configurations of light sources of the light emitting unit;

FIGS. 5A to 5D are diagrams describing a relationship between a light emitting element array and a lens;

FIGS. 6A and 6B are diagrams describing the relationship between the light emitting element array and the lens;

FIG. 7 is a diagram describing a configuration of a light emitting unit to which Exemplary embodiment 2 is applied, and is a view of the light emitting unit as viewed in a +z direction from a −z direction side;

FIG. 8 is a diagram showing an example of configurations of a light emitting unit and a light emission drive unit to which Exemplary Embodiment 3 is applied;

FIG. 9 is a diagram showing a comparative example of arrangement of drivers, and is a view of the light emitting unit, and the drivers and a fan-out buffer constituting the light emission drive unit as viewed in the +z direction from the −z direction side; and

FIG. 10 is a diagram showing an example of configurations of the light emitting unit and the light emission drive unit in a case where the light emitting unit has four light sources.

### DETAILED DESCRIPTION

Hereinafter, exemplary embodiments of the present invention will be described in detail with reference to the accompanying drawings.

The technical scope of the present invention is not limited to the scope to be described below as an exemplary embodiment. It is clear from the description of the claims that a combination of a plurality of examples and various modifications or improvements to the exemplary embodiment described above are also included in the technical scope of the present invention.

### Exemplary Embodiment 1

### Distance Measurement Apparatus 1

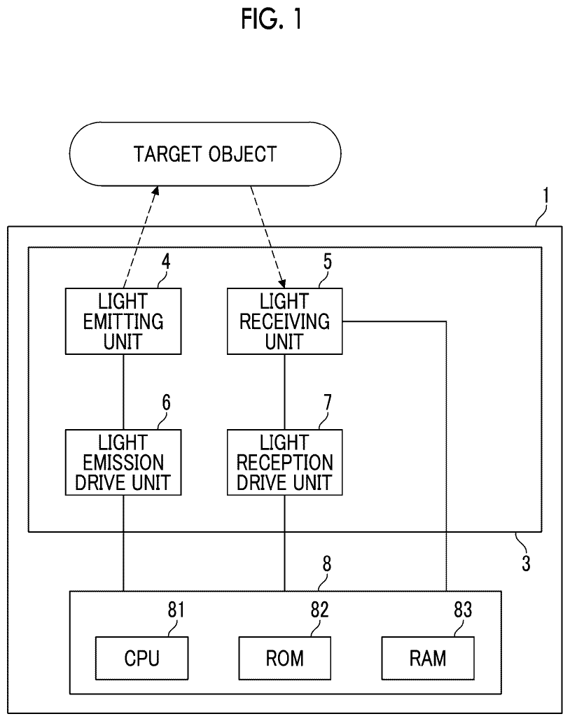

FIG. 1 is a block diagram showing an example of a schematic configuration of a distance measurement apparatus 1 to which the present exemplary embodiment is applied.

The distance measurement apparatus 1 measures a distance to a target object based on a time from a timing at which light is emitted from a light emitting unit 4 to a timing at which the light reflected by the target object is received by a light receiving unit 5. That is, the distance measurement apparatus 1 is an apparatus that performs distance measurement based on a ToF method. The ToF method includes an indirect ToF (iToF) method in which a time is measured from a difference between a phase of emitted light and a phase of received light, and a direct ToF (dToF) method in which a time from emission to reception of light is directly measured. In the present exemplary embodiment, description will be made assuming that the distance measurement apparatus 1 performs distance measurement based on the indirect ToF method.

As shown in FIG. 1, the distance measurement apparatus 1 includes an optical device 3 and a control unit 8.

The optical device 3 includes the light emitting unit 4 that emits light toward a predetermined region, the light receiving unit 5 that receives light reflected by the target object existing in an irradiation region of the light emitted from the light emitting unit 4, a light emission drive unit 6 that drives the light emitting unit 4, and a light reception drive unit 7 that drives the light receiving unit 5. The light emitting unit 4 or a combination of the light emitting unit 4 and the light emission drive unit 6 is an example of a light emitting device.

### Control Unit 8

The control unit 8 controls the operations of the light emitting unit 4 and the light receiving unit 5 of the optical device 3.

In addition, the control unit 8 acquires a result of the light reception by the light receiving unit 5, and measures a distance from the distance measurement apparatus 1 to the target object by the ToF method based on a result of the light reception.

The control unit 8 is an example of a calculation unit.

The control unit 8 is configured of a central processing unit (CPU) 81, a read only memory (ROM) 82, and a random access memory (RAM) 83.

The CPU 81 is an example of a processor, and implements each function, which will be described below, by loading various programs stored in the ROM 82 or the like into the RAM 83 and executing the programs. The RAM 83 is a memory used as a work memory or the like of the CPU 81. The ROM 82 is a memory that stores various programs and the like executed by the CPU 81.

Here, the program executed by the CPU 81 may be provided in a state of being stored in a computer-readable recording medium such as a magnetic recording medium (a magnetic tape, a magnetic disk, or the like), an optical recording medium (an optical disk or the like), a magneto-optical recording medium, or a semiconductor memory. In addition, the program executed by the CPU 81 may be provided by using a communication section such as the Internet.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device). In the embodiments above, the term “processor” is broad enough to encompass one processor or plural processors in collaboration which are located physically apart from each other but may work cooperatively. The order of operations of the processor is not limited to one described in the embodiments above, and may be changed.

### Light Emitting Unit 4

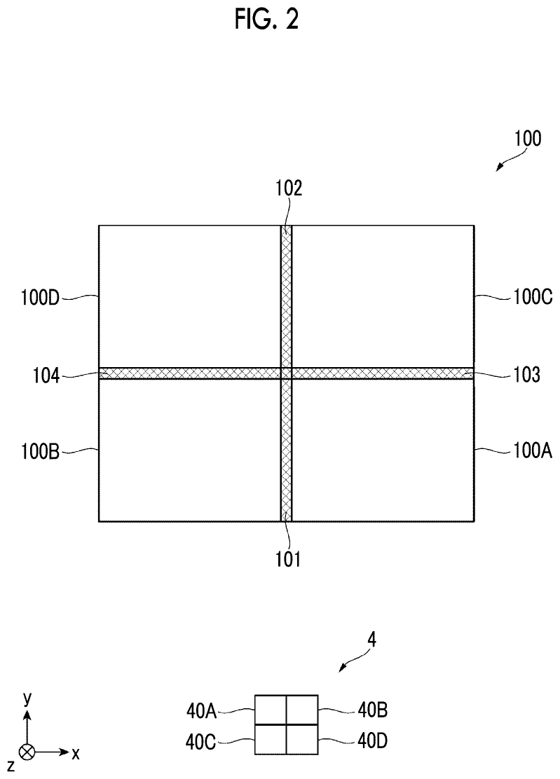

FIG. 2 is a diagram showing the light emitting unit 4 according to the present exemplary embodiment and an irradiation surface 100 that is irradiated with light emitted from the light emitting unit 4. In FIG. 2, a right direction of a paper plane is defined as a +x direction, an upper direction of the paper plane is defined as a +y direction, and a back side of the paper plane is defined as a +z direction. Opposite directions of the directions are defined as −x, −y, and −z directions, respectively. In FIG. 2, the light emitting unit 4 and the irradiation surface 100 are shown to be shifted in the up-down direction (±y direction) of the paper plane, but in reality, the light emitting unit 4 and the irradiation surface 100 are disposed to face each other. In FIG. 2, the light emitting unit 4 is located in the front side direction (−z direction) of the paper plane, and the irradiation surface 100 is located in the back side direction (+z direction) of the paper plane. That is, FIG. 2 is a view of the light emitting unit 4 that emits light to the irradiation surface 100 as viewed from a side opposite to a side on which the light emitting unit 4 emits light.

The light emitting unit 4 has a plurality of (four in this example) light sources 40A, 40B, 40C, and 40D that irradiate different irradiation regions 100A, 100B, 100C, and 100D of the irradiation surface 100 with light beams. In other words, the light emitting unit 4 has the light source 40A that irradiates the irradiation region 100A of the irradiation surface 100 with light, the light source 40B that irradiates the irradiation region 100B with light, the light source 40C that irradiates the irradiation region 100C with light, and the light source 40D that irradiates the irradiation region 100D with light.

Here, the fact that the irradiation region 100A and the irradiation region 100B are different means that the irradiation region 100A and the irradiation region 100B do not coincide with each other, and the irradiation region 100A and the irradiation region 100B may have an overlapping portion. The same applies to other combinations of the irradiation regions 100A, 100B, 100C, and 100D. A relationship between the irradiation regions 100A, 100B, 100C, and 100D will be described in detail below.

The light sources 40A, 40B, 40C, and 40D are disposed to be parallel to each other in the x direction and the y direction. It should be noted that the light sources 40A, 40B, 40C, and 40D are disposed such that the light source 40A and the light source 40B are parallel to each other in the x direction, the light source 40C and the light source 40D are parallel to each other in the x direction, the light source 40A and the light source 40C are parallel to each other in the y direction, and the light source 40B and the light source 40D are parallel to each other in the y direction. In this example, the light source 40A is disposed on the −x direction side with respect to the light source 40B and is disposed on the +y direction side with respect to the light source 40C. The light source 40B is disposed on the +x direction side with respect to the light source 40A and is disposed on the +y direction side with respect to the light source 40D. The light source 40C is disposed on the −y direction side with respect to the light source 40A and is disposed on the −x direction side with respect to the light source 40D. The light source 40D is disposed on the −y direction side with respect to the light source 40B and is disposed on the +x direction side with respect to the light source 40C.

The arrangement of the light sources 40A, 40B, 40C, and 40D is not limited to this.

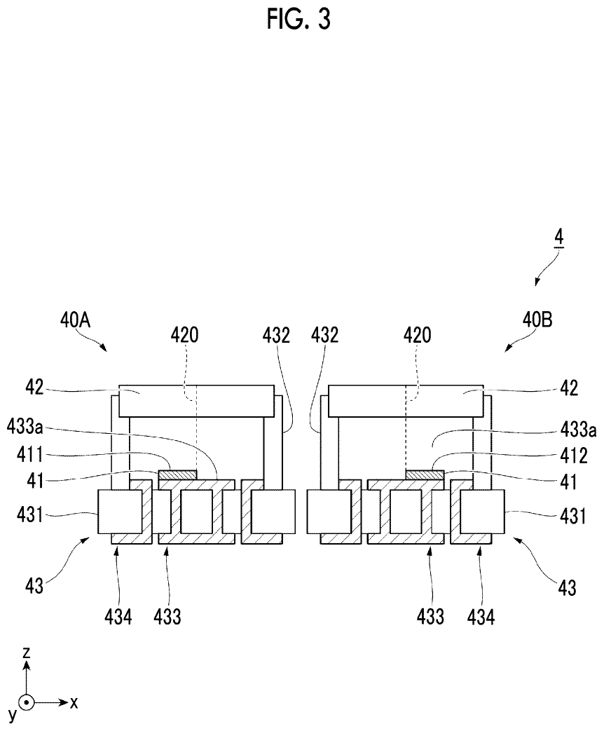

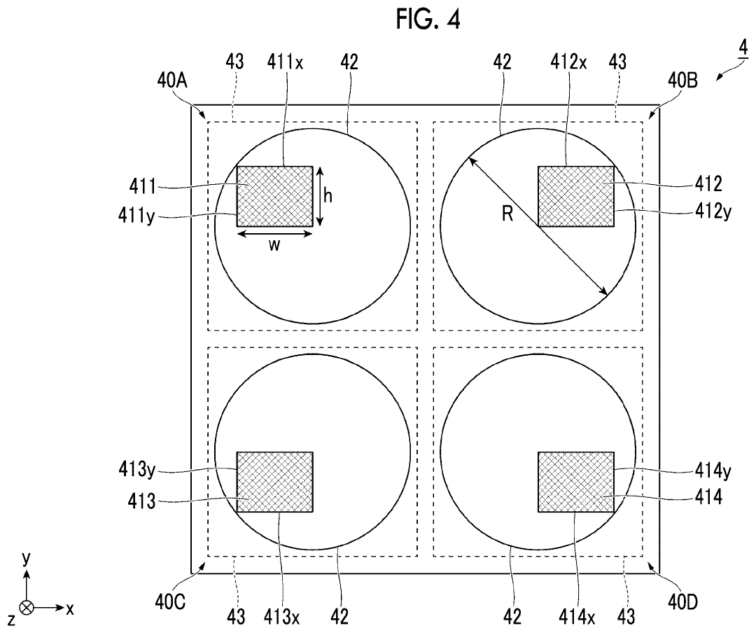

FIGS. 3 and 4 are diagrams describing configurations of the light sources 40A, 40B, 40C, and 40D of the light emitting unit 4. FIG. 3 is a cross-sectional view taken along a zx plane that passes through two light sources 40A and 40B located on the +y direction side among four light sources 40A, 40B, 40C, and 40D included in the light emitting unit 4. FIG. 4 is a view of the light emitting unit 4 as viewed in the +z direction from the −z direction side. In FIGS. 3 and 4, a configuration other than the light sources 40A, 40B, 40C, and 40D, such as a housing that accommodates the light sources 40A, 40B, 40C, and 40D or a driver that drives the light sources 40A, 40B, 40C, and 40D, is not shown. In addition, in FIG. 4, a detailed structure of a first electrode 433 and a second electrode 434 (both shown in FIG. 3) of a sub-mount substrate 43, which will be described below, is omitted.

In the light emitting unit 4 according to the present exemplary embodiment, the light sources 40A, 40B, 40C, and 40D have the same configuration except for a relative position of a light emitting element array 41 with respect to a lens 42, as will be described below.

Each of the light sources 40A, 40B, 40C, and 40D has a light emitting element array 41 that emits light in the +z direction. In addition, each of the light sources 40A, 40B, 40C, and 40D has a lens 42 that refracts the light emitted from the light emitting element array 41. In addition, each of the light sources 40A, 40B, 40C, and 40D has a sub-mount substrate 43 that supports the light emitting element array 41 and the lens 42 such that the light emitting element array 41 is disposed at a predetermined relative position with respect to the lens 42.

The light emitting element array 41 has a light emitting surface in which a plurality of vertical cavity surface emitting lasers (VCSELs) are arranged. The light emitting surface indicates a region of a surface of a portion that is actually emitting light. In the present exemplary embodiment, a region connecting an outer periphery of a region in which the plurality of VCSELs are arranged is the light emitting surface. Even in a case where a shape of a substrate on which the VCSELs are arranged is a quadrangle, in a case where the region in which the VCSELs are arranged spreads out in an elliptical shape, the light emitting surface indicates the elliptical region, and in a case where the region in which the VCSELs are arranged spreads out in a triangular shape, the light emitting surface indicates the triangular region. Hereinafter, the light emitting surface of the light emitting element array 41 included in the light source 40A will be referred to as a light emitting surface 411, the light emitting surface of the light emitting element array 41 included in the light source 40B will be referred to as a light emitting surface 412, the light emitting surface of the light emitting element array 41 included in the light source 40C will be referred to as a light emitting surface 413, and the light emitting surface of the light emitting element array 41 included in the light source 40D will be referred to as a light emitting surface 414.

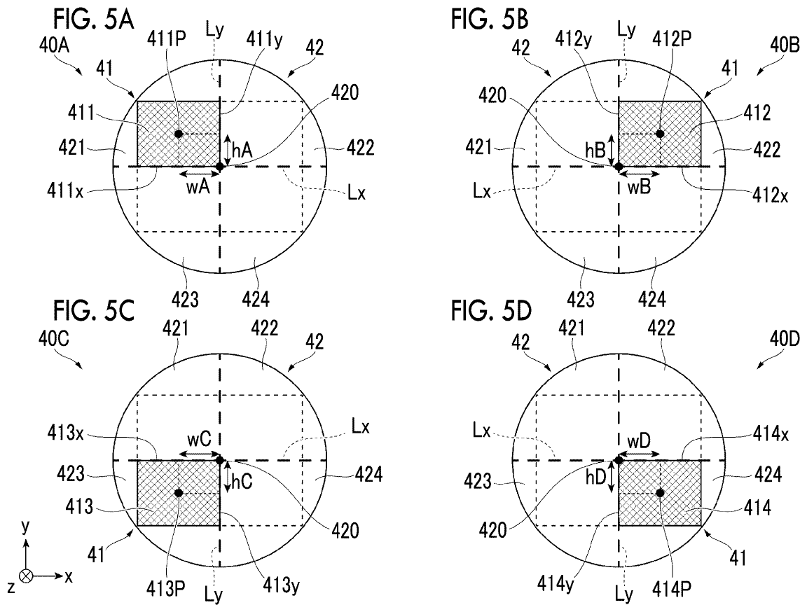

The light emitting element array 41 of the light source 40A is disposed such that the light emitting surface 411 is located along an xy plane. As shown in FIG. 5A to be described below, the light emitting surface 411 has a rectangular shape having a long side 411x extending in the x direction and a short side 411y extending in they direction. Similarly, the light emitting element array 41 of the light source 40B is disposed such that the light emitting surface 412 is located along the xy plane. As shown in FIG. 5B to be described below, the light emitting surface 412 has a rectangular shape having a long side 412x extending in the x direction and a short side 412y extending in the y direction. In addition, the light emitting element array 41 of the light source 40C is disposed such that the light emitting surface 413 is located along the xy plane. As shown in FIG. 5C to be described below, the light emitting surface 413 has a rectangular shape having a long side 413x extending in the x direction and a short side 413y extending in the y direction. In addition, the light emitting element array 41 of the light source 40D is disposed such that the light emitting surface 414 is located along the xy plane. As shown in FIG. 5D to be described below, the light emitting surface 414 has a rectangular shape having a long side 414x extending in the x direction and a short side 414y extending in the y direction.

Hereinafter, a length in the x direction of the light emitting element array 41 (that is, lengths of the long sides 411x to 414x) will be referred to as a length w, and a length in the y direction (that is, lengths of the short sides 411y to 414y) will be referred to as a length h.

The light emitting element arrays 41 of the respective light sources 40A, 40B, 40C, and 40D emit light in the +z direction from the light emitting surfaces 411 to 414 by the light emission of the VCSEL.

Here, the respective light emitting element arrays 41 of the light sources 40A, 40B, 40C, and 40D of the light emitting unit 4 according to the present exemplary embodiment are independently driven by the light emission drive unit 6 (see FIG. 1) to perform a light emission operation. It should be noted that the light sources 40A, 40B, 40C, and 40D emit light by supplying power to the VCSEL included in the light sources 40A, 40B, 40C, and 40D by the light emission drive unit 6.

Here, the phrase “independently driven” refers to a state in which light is emitted by driving each of the light sources 40A, 40B, 40C, and 40D. The light emission drive unit 6 drives each light emitting element array 41 in response to a control signal from the control unit 8 (see FIG. 1). Therefore, the light emitting element arrays 41 of the light sources 40A, 40B, 40C, and 40D do not necessarily emit light simultaneously. For example, the light emitting element array 41 of the light source 40A can emit light while the light emitting element arrays 41 of the light sources 40B, 40C, and 40D do not emit light.

In addition, the light emitting surfaces 411 to 414 of the light emitting element arrays 41 of the respective light sources 40A, 40B, 40C, and 40D may be divided into a plurality of light emitting sections that are independently driven by the light emission drive unit 6 to perform the light emission operation. It should be noted that the light emitting surfaces 411 to 414 of the light emitting element arrays 41 may be divided into a plurality of light emitting sections including at least one VCSEL.

The lens 42 is provided on the +z direction side with respect to the light emitting element array 41. It should be noted that the lens 42 is provided on a downstream side of the light emitting element array 41 in a direction in which the light emitting element array 41 emits light. In addition, the lenses 42 are provided to face the light emitting surfaces 411 to 414 of the light emitting element arrays 41. As a result, the light beams emitted from the light emitting surfaces 411 to 414 of the light emitting element arrays 41 in the +z direction are incident into the lenses 42.

In addition, the lens 42 is disposed such that an optical axis 420 extends in the z direction. The optical axis 420 corresponds to a center of the light emitted from the lens 42 in the x direction and the y direction in a case where it is assumed that the light is uniformly incident into the entire lens 42. Therefore, the optical axis 420 is determined as a characteristic of the lens 42 regardless of the light actually incident into the lens 42. The lenses 42 refract the light beams emitted from the light emitting surfaces 411 to 414 of the light emitting element arrays 41 in a direction intersecting the z direction, thereby expanding the irradiation regions of the light beams in the +z direction.

The sub-mount substrate 43 supports the light emitting element array 41 and the lens 42 such that the light emitting element array 41 and the lens 42 are fixed and the light emitting element array 41 is located at a predetermined relative position with respect to the lens 42.

The sub-mount substrate 43 has an insulating substrate 431 made of AlN, SiC, or the like, and a support portion 432 that extends from a periphery of the insulating substrate 431 in a +z direction and supports the lens 42. In addition, the sub-mount substrate 43 has a pad portion 433a that is formed on a surface of the insulating substrate 431 on the +z direction side and on which the light emitting element array 41 is loaded, and has a first electrode 433 that supplies power to the light emitting element array 41 via the pad portion 433a. In addition, the sub-mount substrate 43 has a second electrode 434 that is connected to the light emitting element array 41 via a bonding wire (not shown) or the like and that supplies power to the light emitting element array 41.

The light emitting element array 41 is fixed to the sub-mount substrate 43 on the pad portion 433a of the first electrode 433 such that the light emitting surfaces 411 to 414 face the +z direction. In addition, the lens 42 is fixed to the sub-mount substrate 43 at an end part of the support portion 432 on the +z direction side such that the optical axis 420 extends in the z direction.

In the present exemplary embodiment, in the light sources 40A, 40B, 40C, and 40D, the light emitting element arrays 41 and the lenses 42 are fixed to the respective sub-mount substrates 43 such that distances between the light emitting surfaces 411 to 414 of the light emitting element arrays 41 and the lenses 42 in the z direction are equal to each other.

FIGS. 5A to 5D are diagrams describing a relationship between the light emitting element array 41 and the lens 42. FIG. 5A shows the light emitting element array 41 and the lens 42 in the light source 40A, FIG. 5B shows the light emitting element array 41 and the lens 42 in the light source 40B, FIG. 5C shows the light emitting element array 41 and the lens 42 in the light source 40C, and FIG. 5D shows the light emitting element array 41 and the lens 42 in the light source 40D. FIGS. 5A to 5D correspond to views of the light emitting element arrays 41 and the lenses 42 in the light sources 40A, 40B, 40C, and 40D as viewed in the +z direction from the −z direction side.

In FIGS. 5A to 5D, a straight line passing through the optical axis 420 of the lens 42 and extending in the x direction, and a straight line passing through the optical axis 420 of the lens 42 and extending in the y direction are shown by broken lines. Hereinafter, the straight line passing through the optical axis 420 of the lens 42 and extending in the x direction will be referred to as a first straight line Lx, and the straight line passing through the optical axis 420 of the lens 42 and extending in the y direction will be referred to as a second straight line Ly.

In addition, in the following description, four regions of the lens 42 divided by the first straight line Lx and the second straight line Ly will be referred to as a first region 421, a second region 422, a third region 423, and a fourth region 424, respectively. The first region 421 is a region of the lens 42 on the +y direction side with respect to the first straight line Lx and on the −x direction side with respect to the second straight line Ly. The second region 422 is a region of the lens 42 on the +y direction side with respect to the first straight line Lx and on the +x direction side with respect to the second straight line Ly. The third region 423 is a region of the lens 42 on the −y direction side with respect to the first straight line Lx and on the −x direction side with respect to the second straight line Ly. The fourth region 424 is a region of the lens 42 on the −y direction side with respect to the first straight line Lx and on the +x direction side with respect to the second straight line Ly.

The lens 42 has a circular shape with the optical axis 420 as the center in a case of being viewed along the z direction. The lens 42 has an axisymmetric optical property with the optical axis 420 as the center. More specifically, the lens 42 refracts the light incident along the +z direction in a direction approaching the optical axis 420. That is, the lens 42 refracts the light incident into the first region 421 in the +x direction and the −y direction. In addition, the lens 42 refracts the light incident into the second region 422 in the −x direction and the −y direction. In addition, the lens 42 refracts the light incident into the third region 423 in the +x direction and the +y direction. In addition, the lens 42 refracts the light incident into the fourth region 424 in the −x direction and the +y direction. Further, the lens 42 has an optical property of refracting incident light more larger as the incident light is directed from the optical axis 420 toward a circumference along a radial direction. The lens 42 does not refract light incident into the optical axis 420.

As described above, the light sources 40A, 40B, 40C, and 40D have different positions of the light emitting element array 41 with respect to the lens 42.

As shown in FIG. 5A, in the light source 40A, the light emitting element array 41 and the lens 42 are disposed such that a center 411P of the light emitting surface 411 is located to be shifted in the −x direction and the +y direction with respect to the optical axis 420 of the lens 42. The center 411P of the light emitting surface 411 is an example of a center of the light emitting element array. In the present exemplary embodiment, since the light emitting surface 411 has a rectangular shape, the center 411P is a center of the rectangle. In this example, a distance in the x direction between the center 411P of the light emitting surface 411 and the optical axis 420 of the lens 42 (hereinafter, referred to as a distance wA) is w/2 (wA=w/2). In addition, a distance in the y direction between the center 411P of the light emitting surface 411 and the optical axis 420 of the lens 42 (hereinafter, referred to as a distance hA) is h/2 (hA=h/2).

As a result, in the light source 40A, the light emitting element array 41 and the lens 42 are disposed such that the light emitting surface 411 overlaps the first region 421 of the lens 42. It should be noted that, in the light source 40A, the light emitting element array 41 and the lens 42 are disposed such that the long side 411x located on the −y direction side overlaps the first straight line Lx of the lens 42 and the short side 411y located on the +x direction side overlaps the second straight line Ly of the lens 42 on the light emitting surface 411. In addition, in the light source 40A, the optical axis 420 of the lens 42 passes through a vertex of the light emitting surface 411 on the +x direction side and the −y direction side.

In addition, as shown in FIG. 5B, in the light source 40B, the light emitting element array 41 and the lens 42 are disposed such that a center 412P of the light emitting surface 412 is located to be shifted in the +x direction and the +y direction with respect to the optical axis 420 of the lens 42. In this example, a distance in the x direction between the center 412P of the light emitting surface 412 and the optical axis 420 of the lens 42 (hereinafter, referred to as a distance wB) is w/2 (wB=w/2). In addition, a distance in the y direction between the center 412P of the light emitting surface 412 and the optical axis 420 of the lens 42 (hereinafter, referred to as a distance hB) is h/2 (hB=h/2).

As a result, in the light source 40B, the light emitting element array 41 and the lens 42 are disposed such that the light emitting surface 412 overlaps the second region 422 of the lens 42. It should be noted that, in the light source 40B, the light emitting element array 41 and the lens 42 are disposed such that the long side 412x located on the −y direction side overlaps the first straight line Lx of the lens 42 and the short side 412y located on the −x direction side overlaps the second straight line Ly of the lens 42 on the light emitting surface 412. In addition, in the light source 40B, the optical axis 420 of the lens 42 passes through a vertex of the light emitting surface 412 on the −x direction side and the −y direction side.

In addition, as shown in FIG. 5C, in the light source 40C, the light emitting element array 41 and the lens 42 are disposed such that a center 413P of the light emitting surface 413 is located to be shifted in the −x direction and the −y direction with respect to the optical axis 420 of the lens 42. In this example, a distance in the x direction between the center 413P of the light emitting surface 413 and the optical axis 420 of the lens 42 (hereinafter, referred to as a distance wC) is w/2 (wC=w/2). In addition, a distance in the y direction between the center 413P of the light emitting surface 413 and the optical axis 420 of the lens 42 (hereinafter, referred to as a distance hC) is h/2 (hC=h/2).

As a result, in the light source 40C, the light emitting element array 41 and the lens 42 are disposed such that the light emitting surface 413 overlaps the third region 423 of the lens 42. It should be noted that, in the light source 40C, the light emitting element array 41 and the lens 42 are disposed such that the long side 413x located on the +y direction side overlaps the first straight line Lx of the lens 42 and the short side 413y located on the +x direction side overlaps the second straight line Ly of the lens 42 on the light emitting surface 413. In addition, in the light source 40C, the optical axis 420 of the lens 42 passes through a vertex of the light emitting surface 413 on the +x direction side and the +y direction side.

In addition, as shown in FIG. 5D, in the light source 40D, the light emitting element array 41 and the lens 42 are disposed such that a center 414P of the light emitting surface 414 is located to be shifted in the +x direction and the −y direction with respect to the optical axis 420 of the lens 42. In this example, a distance in the x direction between the center 414P of the light emitting surface 414 and the optical axis 420 of the lens 42 (hereinafter, referred to as a distance wD) is w/2 (wD=w/2). In addition, a distance in the y direction between the center 414P of the light emitting surface 414 and the optical axis 420 of the lens 42 (hereinafter, referred to as a distance hD) is h/2 (hD=h/2).

As a result, in the light source 40D, the light emitting element array 41 and the lens 42 are disposed such that the light emitting surface 414 overlaps the fourth region 424 of the lens 42. It should be noted that, in the light source 40D, the light emitting element array 41 and the lens 42 are disposed such that the long side 414x located on the +y direction side overlaps the first straight line Lx of the lens 42 and the short side 414y located on the −x direction side overlaps the second straight line Ly of the lens 42 on the light emitting surface 414. In addition, in the light source 40D, the optical axis 420 of the lens 42 passes through a vertex of the light emitting surface 414 on the −x direction side and the +y direction side.

As described above, in the light emitting unit 4 according to the present exemplary embodiment, the light emitting surface 411 of the light emitting element array 41 in the light source 40A, the light emitting surface 412 of the light emitting element array 41 in the light source 40B, the light emitting surface 413 of the light emitting element array 41 in the light source 40C, and the light emitting surface 414 of the light emitting element array 41 in the light source 40D overlap the first straight line Lx and the second straight line Ly of the lens 42. It should be noted that, in the light sources 40A, 40B, 40C, and 40D, there is no gap between the relative positions of the light emitting surfaces 411, 412, 413, and 414 with respect to the lens 42.

The center 411P of the light emitting surface 411 means a rotation center in a case where the shape of the light emitting surface 411 is n-fold symmetric (n is a natural number of 2 or more). Since the light emitting surface 411 according to the present exemplary embodiment has a rectangular shape with two-fold symmetry, the center 411P of the light emitting surface 411 is an intersection of diagonal lines, which is a rotation center.

The same applies to the center 412P of the light emitting surface 412, the center 413P of the light emitting surface 413, and the center 414P of the light emitting surface 414.

Here, in the light emitting unit 4, the sub-mount substrate 43 of the light source 40A and the sub-mount substrate 43 of the light source 40B are disposed such that the light emitting surface 411 of the light source 40A and the light emitting surface 412 of the light source 40B are parallel to each other in the x direction.

Similarly, in the light emitting unit 4, the sub-mount substrate 43 of the light source 40A and the sub-mount substrate 43 of the light source 40C are disposed such that the light emitting surface 411 of the light source 40A and the light emitting surface 413 of the light source 40C are parallel to each other in the y direction.

Further, in the light emitting unit 4, the sub-mount substrate 43 of the light source 40B and the sub-mount substrate 43 of the light source 40D are disposed such that the light emitting surface 412 of the light source 40B and the light emitting surface 414 of the light source 40D are parallel to each other in the y direction.

Further, in the light emitting unit 4, the sub-mount substrate 43 of the light source 40C and the sub-mount substrate 43 of the light source 40D are disposed such that the light emitting surface 413 of the light source 40C and the light emitting surface 414 of the light source 40D are parallel to each other in the x direction.

As described above, in the present exemplary embodiment, the light emitting unit 4 can be configured by the arrangement of the sub-mount substrates 43 of the respective light sources 40A, 40B, 40C, and 40D in which the light emitting element array 41 and the lens 42 are fixed.

As described above, in the light emitting unit 4 according to the present exemplary embodiment, the light emitting element array 41 and the lens 42 of each light source 40 have a common configuration. In the respective light sources 40, the light emitting element arrays 41 and the lenses 42 are fixed to the sub-mount substrates 43 such that distances between the light emitting surfaces 411, 412, 413, and 414 of the light emitting element arrays 41 and the lenses 42 in the z direction are equal to each other.

As a result, in the respective light sources 40, a deviation of illuminance between the irradiation regions 100A, 100B, 100C, and 100D of the irradiation surface 100, which are irradiated with the light beams from the respective light sources 40, is suppressed, for example, as compared with a case where the distances between the light emitting surfaces 411, 412, 413, and 414 of the light emitting element arrays 41 and the lenses 42 in the z direction are made different.

Irradiation Region with Light from Light Emitting Unit 4

Subsequently, the irradiation regions 100A, 100B, 100C, and 100D of the irradiation surface 100, which are irradiated with the light beams emitted from the light sources 40A, 40B, 40C, and 40D of the light emitting unit 4, will be described with reference to FIGS. 2 to 4.

The irradiation surface 100 is a surface that is irradiated with the light from each light source 40, the surface being orthogonal to a direction in which light is emitted at a certain distance in a direction (+z direction) in which each light source 40 emits light from the light emitting unit 4. The irradiation surface 100 extends in the x direction and the y direction at a certain distance in the +z direction.

In the light source 40A, the light emitted from the light emitting surface 411 of the light emitting element array 41 is incident into the first region 421 of the lens 42 along the +z direction. Then, the light incident into the first region 421 of the lens 42 is refracted in the +x direction and the −y direction by the optical property of the lens 42, and is emitted from the light source 4A.

In the light source 40B, the light emitted from the light emitting surface 412 of the light emitting element array 41 is incident into the second region 422 of the lens 42 along the +z direction. Then, the light incident into the second region 422 of the lens 42 is refracted in the −x direction and the −y direction by the optical property of the lens 42, and is emitted from the light source 4B.

In the light source 40C, the light emitted from the light emitting surface 413 of the light emitting element array 41 is incident into the third region 423 of the lens 42 along the +z direction. Then, the light incident into the third region 423 of the lens 42 is refracted in the +x direction and the +y direction by the optical property of the lens 42, and is emitted from the light source 4C.

In the light source 40D, the light emitted from the light emitting surface 414 of the light emitting element array 41 is incident into the fourth region 424 of the lens 42 along the +z direction. Then, the light incident into the fourth region 424 of the lens 42 is refracted in the −x direction and the +y direction by the optical property of the lens 42, and is emitted from the light source 4D.

As a result, the light emitted from the light source 40A is emitted to the irradiation region 100A located on the +x direction side and the −y direction side on the irradiation surface 100. In addition, the light emitted from the light source 40B is emitted to the irradiation region 100B located on the −x direction side and the −y direction side on the irradiation surface 100. In addition, the light emitted from the light source 40C is emitted to the irradiation region 100C located on the +x direction side and the +y direction side on the irradiation surface 100. In addition, the light emitted from the light source 40D is emitted to the irradiation region 100D located on the −x direction side and the +y direction side on the irradiation surface 100.

As shown in FIG. 2, in the irradiation surface 100, the irradiation region 100A and the irradiation region 100B are parallel to each other in the x direction, the irradiation region 100C and the irradiation region 100D are parallel to each other in the x direction, the irradiation region 100A and the irradiation region 100C are parallel to each other in the y direction, and the irradiation region 100B and the irradiation region 100D are parallel to each other in the y direction. More specifically, the irradiation region 100A is parallel to the irradiation region 100B on the +x direction side and is parallel to the irradiation region 100C on the −y direction side. In addition, the irradiation region 100B is parallel to the irradiation region 100A on the −x direction side and is parallel to the irradiation region 100D on the −y direction side. The irradiation region 100C is parallel to the irradiation region 100A on the +y direction side and is parallel to the irradiation region 100D on the +x direction side. The irradiation region 100D is parallel to the irradiation region 100B on the +y direction side and is parallel to the irradiation region 100C on the −x direction side.

It should be noted that the arrangement of the irradiation regions 100A, 100B, 100C, and 100D that are parallel to each other in the irradiation surface 100 is inverted in the x direction and the y direction with respect to the arrangement of the light emitting surfaces 411, 412, 413, and 414 with respect to the lenses 42 of the light sources 40A, 40B, 40C, and 40D.

As described above, in the light sources 40A, 40B, 40C, and 40D, the light emitting element arrays 41 and the lenses 42 are disposed such that there is no gap between the relative positions of the light emitting surfaces 411, 412, 413, and 414 with respect to the lens 42.

As a result, on the irradiation surface 100, formation of a non-irradiation portion which is not irradiated with the light beams from the light sources 40A, 40B, 40C, and 40D is suppressed between the irradiation regions 100A, 100B, 100C, and 100D parallel to each other.

In the irradiation surface 100, partial regions in the irradiation regions 100A, 100B, 100C, and 100D parallel to each other may overlap each other.

In the irradiation surface 100 of FIG. 2, an overlapping region 101 in which partial regions of the irradiation region 100A and the irradiation region 100B in the x direction overlap each other is formed. In addition, in the irradiation surface 100 of FIG. 2, an overlapping region 102 in which partial regions of the irradiation region 100C and the irradiation region 100D in the x direction overlap each other is formed. In addition, in the irradiation surface 100 of FIG. 2, an overlapping region 103 in which partial regions of the irradiation region 100A and the irradiation region 100C in the y direction overlap each other is formed. In addition, in the irradiation surface 100 of FIG. 2, an overlapping region 104 in which partial regions of the irradiation region 100B and the irradiation region 100D in the y direction overlap each other is formed.

### Relationship Between Light Emitting Element Array 41 and Lens 42

Subsequently, a relationship between the light emitting element array 41 and the lens 42 will be described in more detail.

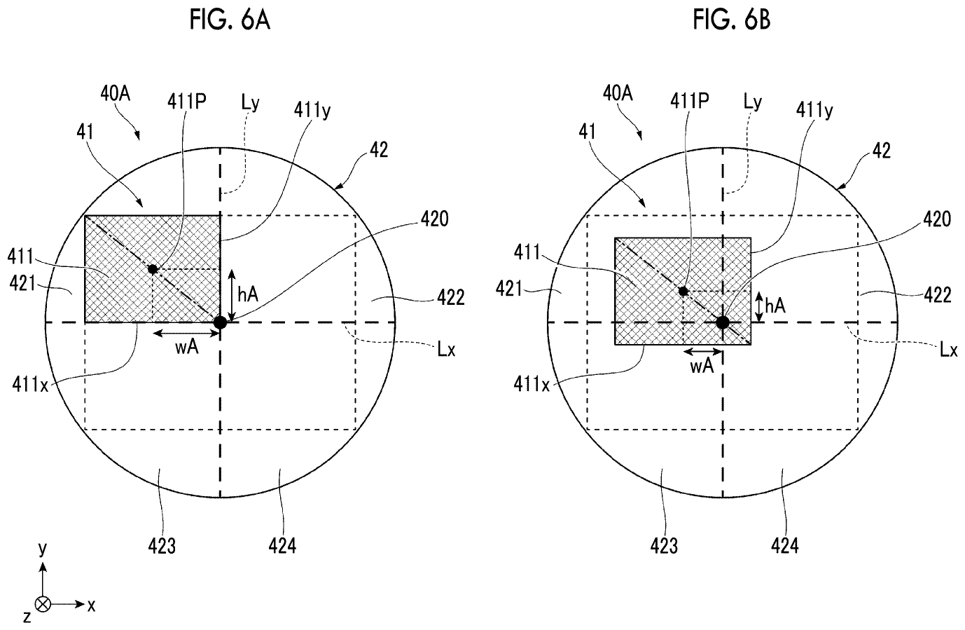

FIGS. 6A and 6B are diagrams describing the relationship between the light emitting element array 41 and the lens 42. FIGS. 6A and 6B correspond to views of the light emitting element array 41 and the lens 42 in the light source 40A as viewed in the +z direction from the −z direction side. In FIG. 6A and FIG. 6B, the distance between the center 411P of the light emitting surface 411 in the light emitting element array 41 and the optical axis 420 of the lens 42 is different. The relationship between the light emitting element array 41 and the lens 42 in FIG. 6A is the same as the relationship in FIG. 6B.

In the example shown in FIG. 6A, the distance wA in the x direction between the center 411P of the light emitting surface 411 and the optical axis 420 of the lens 42 is w/2 (wA=w/2). In addition, the distance hA in the y direction between the center 411P of the light emitting surface 411 and the optical axis 420 of the lens 42 is h/2 (hA=h/2).

In the example shown in FIG. 6A, the light emitting surface 411 overlaps the first region 421 of the lens 42, and does not overlap the second region 422, the third region 423, and the fourth region 424 of the lens 42, which are parallel to the first region 421.

In addition, in the example shown in FIG. 6B, the distance wA in the x direction between the center 411P of the light emitting surface 411 and the optical axis 420 of the lens 42 is w/4 (wA=w/4). In addition, the distance hA in the y direction between the center 411P of the light emitting surface 411 and the optical axis 420 of the lens 42 is h/4 (hA=h/4).

In the example shown in FIG. 6B, the light emitting surface 411 overlaps the first region 421 of the lens 42, in which a part of the light emitting surface 411 on the +x direction side overlaps the second region 422 and the fourth region 424 of the lens 24, and a part of the light emitting surface 411 on the −y direction side overlaps the third region 423 and the fourth region 424 of the lens 24.

First, the light emitting element array 41 and the lens 42 of the light source 40A and the light emitting element array 41 and the lens 42 of the light source 40B (see FIG. 3 and FIG. 5B) that are parallel to each other in the x direction, which is one direction, will be described. Here, the light emitting element array 41 of the light source 40A is an example of a first light emitting element array, and the lens 42 of the light source 40A is an example of a first optical system. In addition, the light emitting element array 41 of the light source 40B is an example of a second light emitting element array, and the lens 42 of the light source 40B is an example of a second optical system.

In the light emitting unit 4 according to the present exemplary embodiment, the distance wA between the center 411P of the light emitting surface 411 and the optical axis 420 of the lens 42 in the light source 40A and the distance wB between the center 412P of the light emitting surface 412 and the optical axis 420 of the lens 42 in the light source 40B in the x direction are, for example, preferably w/4 or more and w/2 or less.

In a case where the distance wA between the center 411P of the light emitting surface 411 and the optical axis 420 of the lens 42 in the light source 40A and the distance wB between the center 412P of the light emitting surface 412 and the optical axis 420 of the lens 42 in the light source 40B in the x direction are w/2 or less, the formation of the non-irradiated portion may be suppressed between the irradiation region 100A and the irradiation region 100B that are parallel to each other in the x direction on the irradiation surface 100. It should be noted that the distance wA between the center 411P of the light emitting surface 411 and the optical axis 420 of the lens 42 in the light source 40A or the distance wB between the center 412P of the light emitting surface 412 and the optical axis 420 of the lens 42 in the light source 40B exceeds w/2, the non-irradiated portion is likely to be formed between the irradiation region 100A and the irradiation region 100B on the irradiation surface 100.

In addition, in a case where the distance wA between the center 411P of the light emitting surface 411 and the optical axis 420 of the lens 42 in the light source 40A and the distance wB between the center 412P of the light emitting surface 412 and the optical axis 420 of the lens 42 in the light source 40B in the x direction are w/4 or more, an increase in size of the overlapping region 101 in which the irradiation region 100A and the irradiation region 100B that are parallel to each other in the x direction on the irradiation surface 100 overlap each other is suppressed as compared with a case where the distance wA or the distance wB is less than w/4.

In a case where the overlapping region 101 between the irradiation region 100A and the irradiation region 100B increases in size, the width of the irradiation surface 100 in the x direction decreases, and the area of the entire irradiation surface 100 decreases. In this case, a region in which the distance to the target object can be measured by irradiating the target object with light from the light emitting unit 4 (see FIG. 1) is narrowed.

Although detailed description is omitted here, for the light emitting element array 41 and the lens 42 of the light source 40C (see FIG. 4 and FIG. 5C) and the light emitting element array 41 and the lens 42 of the light source 40D (see FIG. 4 and FIG. 5D) that are parallel to each other in the x direction, the distance wC between the center 413P of the light emitting surface 413 and the optical axis 420 of the lens 42 and the distance wD between the center 414P of the light emitting surface 414 and the optical axis 420 of the lens 42 are, for example, preferably w/4 or more and w/2 or less, as with the light source 40A and the light source 40B.

Subsequently, the light emitting element array 41 and the lens 42 of the light source 40A and the light emitting element array 41 and the lens 42 of the light source 40C that are parallel to each other in the y direction, which is another direction, will be described. Here, the light emitting element array 41 of the light source 40A is an example of a first light emitting element array, and the lens 42 of the light source 40A is an example of a first optical system. In addition, the light emitting element array 41 of the light source 40C is an example of a third light emitting element array, and the lens 42 of the light source 40C is an example of a third optical system.

In the light emitting unit 4 according to the present exemplary embodiment, the distance hA between the center 411P of the light emitting surface 411 and the optical axis 420 of the lens 42 in the light source 40A and the distance hC between the center 413P of the light emitting surface 413 and the optical axis 420 of the lens 42 in the light source 40C in the y direction are, for example, preferably h/4 or more and h/2 or less.

In a case where the distance hA between the center 411P of the light emitting surface 411 and the optical axis 420 of the lens 42 in the light source 40A and the distance hC between the center 413P of the light emitting surface 413 and the optical axis 420 of the lens 42 in the light source 40C in the y direction are h/2 or less, the formation of the non-irradiated portion may be suppressed between the irradiation region 100A and the irradiation region 100C that are parallel to each other in the y direction on the irradiation surface 100. It should be noted that the distance hA between the center 411P of the light emitting surface 411 and the optical axis 420 of the lens 42 in the light source 40A or the distance hC between the center 413P of the light emitting surface 413 and the optical axis 420 of the lens 42 in the light source 40C exceeds h/2, the non-irradiated portion is likely to be formed between the irradiation region 100A and the irradiation region 100C on the irradiation surface 100.

In addition, in a case where the distance hA between the center 411P of the light emitting surface 411 and the optical axis 420 of the lens 42 in the light source 40A and the distance hC between the center 413P of the light emitting surface 413 and the optical axis 420 of the lens 42 in the light source 40C in the y direction are h/4 or more, an increase in size of the overlapping region 103 in which the irradiation region 100A and the irradiation region 100C that are parallel to each other in the y direction on the irradiation surface 100 overlap each other is suppressed as compared with a case where the distance hA or the distance hC is less than h/4.

In a case where the overlapping region 103 between the irradiation region 100A and the irradiation region 100C increases in size, the width of the irradiation surface 100 in the y direction decreases, and the area of the entire irradiation surface 100 decreases. In this case, a region in which the distance to the target object can be measured by irradiating the target object with light from the light emitting unit 4 is narrowed.

Here, in the light source 40A according to the present exemplary embodiment, as shown in FIGS. 6A and 6B, for example, it is preferable that the optical axis 420 of the lens 42 is located on any one diagonal line of the rectangular light emitting surface 411 of the light emitting element array 41. In FIGS. 6A and 6B, the diagonal line of the light emitting surface 411 is shown by a one-dot chain line.

In a case where the optical axis 420 of the lens 42 is located on the diagonal line of the light emitting surface 411, the light emitting surface 411 is prevented from being disposed to be biased in any of the x direction or the y direction with respect to the optical axis 420. In this case, either the overlapping region 101 between the irradiation region 100A and the irradiation region 100B or the overlapping region 103 between the irradiation region 100A and the irradiation region 100C is prevented from being excessively large as compared with a case where the optical axis 420 of the lens 42 is located at a position deviated from the diagonal line of the light emitting surface 411.

Further, in the light source 40A according to the present exemplary embodiment, for example, it is preferable that the optical axis 420 of the lens 42 passes through any one vertex of the rectangular light emitting surface 411 of the light emitting element array 41. In the light source 40A of FIG. 6A, the optical axis 420 of the lens 42 passes through the vertex on the +x direction side and the −y direction side of the light emitting surface 411.

In a case where the optical axis 420 of the lens 42 passes through the vertex of the light emitting surface 411, the size of the overlapping region 101 between the irradiation region 100A and the irradiation region 100B and the overlapping region 103 between the irradiation region 100A and the irradiation region 100C can be decreased as compared with a case where the optical axis 420 of the lens 42 does not pass through the vertex of the light emitting surface 411.

Although not shown, in the light sources 40B, 40C, and 40D, similarly to the light source 40A, for example, it is preferable that the optical axis 420 of the lens 42 is located on any one diagonal line of the rectangular light emitting surfaces 412, 413, and 414 of the light emitting element array 41.

Further, in the light sources 40B, 40C, and 40D, similarly to the light source 40A, for example, it is preferable that the optical axis 420 of the lens 42 passes through any one vertex of the rectangular light emitting surfaces 412, 413, and 414 of the light emitting element array 41.

In the present exemplary embodiment, the case where the light emitting unit 4 is provided with the four light sources 40A, 40B, 40C, and 40D provided such that the irradiation regions 100A, 100B, 100C, and 100D are parallel to each other in the x direction and the y direction on the irradiation surface 100 has been described as an example, but the configuration of the light emitting unit 4 is not limited to this.

The light emitting unit 4 may have a plurality of light sources provided such that a plurality of irradiation regions are parallel to each other in one direction (for example, the x direction) and the irradiation regions are not parallel to each other in another direction (for example, the y direction) on the irradiation surface 100. In this case, the light emitting element array 41 and the lens 42 need only be provided in a plurality of light sources such that the distance between the center of the light emitting surface of the light emitting element array 41 and the optical axis 420 of the lens 42 is in a range of w/4 or more and w/2 or less.

In addition, the light emitting unit 4 may have a plurality of light sources provided such that a plurality of irradiation regions of three or more are parallel to each other in one direction (for example, the x direction) or another direction (for example, the y direction) on the irradiation surface 100.

### Effective Diameter of Lens 42

Subsequently, an effective diameter R (see FIGS. 6A and 6B) of the lens 42 included in the light emitting unit 4 will be described.

In the light emitting unit 4, in a case where the light emitting element array 41 has a rectangular shape in which the length in one direction (for example, the x direction) is w and the length in another direction (for example, the y direction) is h, and n (n is a natural number of 1 or more) light emitting element arrays 41 are parallel to each other in the other direction (y direction), it is preferable that the effective diameter R of the lens 42 is, for example, set to satisfy Equation (1).

$$R \geq 2 \times \sqrt{{w}^{2} + {( \frac{nh}{2} )}^{2}} \qquad ( 1 )$$

In a case where the effective diameter R of the lens 42 satisfies Equation (1), the distance between the optical axis 420 of the lens 42 and the center of the light emitting surface of the light emitting element array 41 is easily secured, for example, as compared with a case where the effective diameter R of the lens 42 is smaller than the range of Equation (1). It should be noted that, in a case where the effective diameter R of the lens 42 is smaller than the range of Equation (1), the light emitting element array 41 may protrude from the outer periphery of the lens 42 depending on the distance between the optical axis 420 of the lens 42 and the center of the light emitting surface of the light emitting element array 41.

### Exemplary Embodiment 2

Hereinafter, Exemplary Embodiment 2 of the present invention will be described.

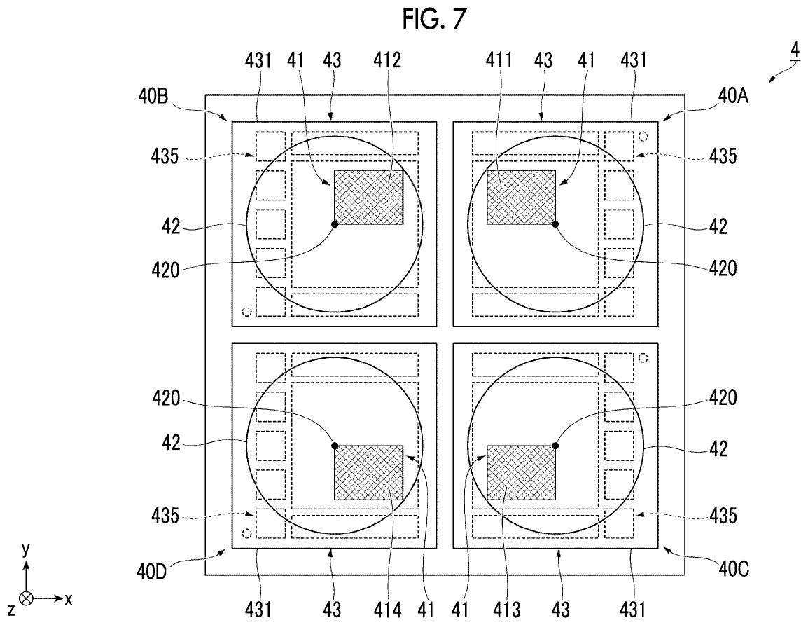

FIG. 7 is a diagram describing a configuration of the light emitting unit 4 to which Exemplary embodiment 2 is applied, and is a view of the light emitting unit 4 as viewed in the +z direction from the −z direction side. In FIG. 7, a wiring 435, which will be described below, of the sub-mount substrate 43 located on the −z direction side (that is, the front side of the paper plane) with respect to the light emitting element array 41 and the lens 42 in each of the light sources 40A, 40B, 40C, and 40D is shown by a broken line.

In the light emitting unit 4 of Exemplary Embodiment 2, the arrangement of the light sources 40A, 40B, 40C, and 40D and the relationship between the sub-mount substrate 43 and the light emitting element array 41, and the lens 42 in each of the light sources 40A, 40B, 40C, and 40D are different from the arrangement and the relationship in the light emitting unit 4 of Exemplary Embodiment 1.

The same configurations as the configurations in Exemplary Embodiment 1 in the present exemplary embodiment are denoted by the same reference numerals, and the detailed description thereof will be omitted here.

In the light emitting unit 4 according to Exemplary Embodiment 2, the light source 40A and the light source 40B are disposed to be parallel to each other in the x direction, the light source 40C and the light source 40D are disposed to be parallel to each other in the x direction, the light source 40A and the light source 40C are disposed to be parallel to each other in the y direction, and the light source 40B and the light source 40D are disposed to be parallel to each other in the y direction. In this example, the light source 40A is disposed on the +x direction side with respect to the light source 40B and is disposed on the +y direction side with respect to the light source 40C. The light source 40B is disposed on the −x direction side with respect to the light source 40A and is disposed on the +y direction side with respect to the light source 40D. The light source 40C is disposed on the −y direction side with respect to the light source 40A and is disposed on the +x direction side with respect to the light source 40D. The light source 40D is disposed on the −y direction side with respect to the light source 40B and is disposed on the −x direction side with respect to the light source 40C.

In addition, in the light emitting unit 4 according to Exemplary Embodiment 2, the sub-mount substrate 43 of the light source 40A and the sub-mount substrate 43 of the light source 40B are disposed such that the light emitting surface 411 of the light source 40A and the light emitting surface 412 of the light source 40B are parallel to each other in the x direction, as in Exemplary Embodiment 1.

Similarly, in the light emitting unit 4, the sub-mount substrate 43 of the light source 40A and the sub-mount substrate 43 of the light source 40C are disposed such that the light emitting surface 411 of the light source 40A and the light emitting surface 413 of the light source 40C are parallel to each other in the y direction.

Further, in the light emitting unit 4, the sub-mount substrate 43 of the light source 40B and the sub-mount substrate 43 of the light source 40D are disposed such that the light emitting surface 412 of the light source 40B and the light emitting surface 414 of the light source 40D are parallel to each other in the y direction.

Further, in the light emitting unit 4, the sub-mount substrate 43 of the light source 40C and the sub-mount substrate 43 of the light source 40D are disposed such that the light emitting surface 413 of the light source 40C and the light emitting surface 414 of the light source 40D are parallel to each other in the x direction.

As described above, in Exemplary Embodiment 2 as well, the light emitting unit 4 can be configured by the arrangement of the sub-mount substrates 43 of the respective light sources 40A, 40B, 40C, and 40D in which the light emitting element array 41 and the lens 42 are fixed.

Here, in the sub-mount substrate 43 according to Exemplary Embodiment 2, a wiring 435 including an electrode (not shown) that supplies power to the light emitting element array 41 is formed on the insulating substrate 431. In this example, the insulating substrate 431 has a rectangular shape. In a case where the sub-mount substrate 43 is disposed such that each side of the insulating substrate 431 extends along the x direction or the y direction and is viewed in the z direction, the shape of the entire wiring 435 is asymmetrical in one direction (the x direction in this example) of the x direction and the y direction and is symmetrical in another direction (the y direction in this example).

In addition, in the light emitting element array 41 according to Exemplary Embodiment 2, the light emitting surfaces 411 to 414 have a rectangular shape with two-fold symmetry, as in Exemplary Embodiment 1.

In the light emitting unit 4 according to Exemplary Embodiment 2, the positional relationship between the light emitting element array 41 and the lens 42 fixed to the sub-mount substrate 43 is different between the light sources 40A and 40D and the light sources 40B and 40C. In other words, in the light emitting unit 4 according to Exemplary Embodiment 2, the positional relationship between the light emitting element array 41 and the lens 42 is common between the light source 40A and the light source 40D, and is common between the light source 40B and the light source 40C.

Specifically, in the light emitting unit 4 according to Exemplary Embodiment 2, a combination of the light emitting element array 41 and the lens 42 fixed to the sub-mount substrate 43 in the light source 40D has a configuration in which a combination of the light emitting element array 41 and the lens 42 fixed to the sub-mount substrate 43 in the light source 40A is rotated by 180 degrees around the optical axis 420 of the lens 42 of the light source 40A.

In this example, the light emitting element array 41 of the light source 40A is an example of a first light emitting element array, and the lens 42 of the light source 40A is an example of a first optical system. In addition, the light emitting element array 41 of the light source 40D is an example of a fourth light emitting element array, and the lens 42 of the light source 40D is an example of a fourth optical system.

In addition, in the light emitting unit 4 according to Exemplary Embodiment 2, a combination of the light emitting element array 41 and the lens 42 fixed to the sub-mount substrate 43 in the light source 40C has a configuration in which a combination of the light emitting element array 41 and the lens 42 fixed to the sub-mount substrate 43 in the light source 40B is rotated by 180 degrees around the optical axis 420 of the lens 42 of the light source 40B.

Here, in FIG. 7, it has been described that, in a case where the shapes of the light emitting surfaces 411 to 414 of the light emitting element arrays 41 included in the light sources 40A, 40B, 40C, and 40D are rectangular shapes with two-fold symmetry, the light source 40A and the light source 40D can have a common configuration, and the light source 40B and the light source 40C can have a common configuration.

Here, in a case where the shapes of the light emitting surfaces 411 to 414 of the light emitting element arrays 41 included in the light sources 40A, 40B, 40C, and 40D are four-fold symmetric shapes such as squares, the light sources 40A, 40B, 40C, and 40D can have a common configuration.

That is, the light source 40B can have a configuration in which the light source 40A is rotated by 90 degrees around the optical axis 420 of the lens 42. More specifically, a combination of the light emitting element array 41 and the lens 42 of the light source 40B can have a configuration in which a combination of the light emitting element array 41 and the lens 42 of the light source 40A is rotated by 90 degrees around the optical axis 420 of the lens 42 of the light source 40A. In this example, the light emitting element array 41 of the light source 40A is an example of a first light emitting element array, and the lens 42 of the light source 40A is an example of a first optical system. In addition, the light emitting element array 41 of the light source 40B is an example of a second light emitting element array, and the lens 42 of the light source 40B is an example of a fourth optical system.

In addition, the light source 40C can have a configuration in which the light source 40A is rotated by −90 degrees (or 270 degrees) around the optical axis 420 of the lens 42. More specifically, a combination of the light emitting element array 41 and the lens 42 of the light source 40C can have a configuration in which a combination of the light emitting element array 41 and the lens 42 of the light source 40A is rotated by −90 degrees (or 270 degrees) around the optical axis 420 of the lens 42 of the light source 40A.

In addition, the light source 40D can have a configuration in which the light source 40A is rotated by 180 degrees around the optical axis 420 of the lens 42. More specifically, a combination of the light emitting element array 41 and the lens 42 of the light source 40D can have a configuration in which a combination of the light emitting element array 41 and the lens 42 of the light source 40A is rotated by 180 degrees around the optical axis 420 of the lens 42 of the light source 40A.

### Exemplary Embodiment 3

Hereinafter, Exemplary Embodiment 3 of the present invention will be described.

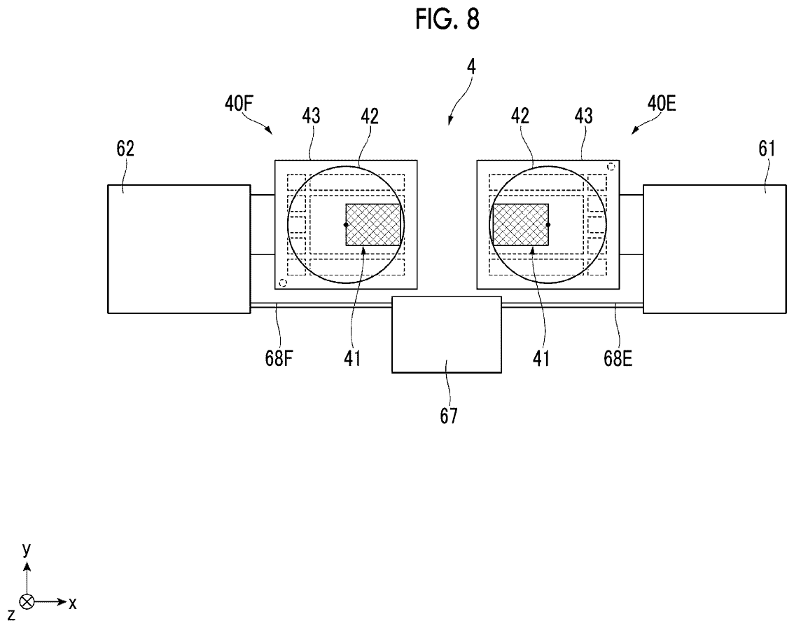

FIG. 8 is a diagram showing an example of configurations of the light emitting unit 4 and the light emission drive unit 6 (see FIG. 1) to which Exemplary Embodiment 3 is applied. FIG. 8 is a view of the light emitting unit 4, and a driver 61, a driver 62, and a fan-out buffer 67 constituting the light emission drive unit 6 as viewed in the +z direction from the −z direction side. FIG. 8 shows a case where the light emitting unit 4 has two light sources 40E and 40F disposed to be parallel to each other in the x direction. In addition, in FIG. 8, the sub-mount substrate 43 located on the −z direction side (that is, the front side of the paper plane) with respect to the light emitting element array 41 and the lens 42 in each of the light sources 40E and 40F is shown by a broken line.

In Exemplary Embodiment 3, the same configurations as the configurations in Exemplary Embodiment 1 and Exemplary Embodiment 2 are denoted by the same reference numerals, and the detailed description thereof will be omitted here.

As described above, in the light emitting unit 4 according to Exemplary Embodiment 3, the two light sources 40E and 40F are disposed to be parallel to each other in the x direction. In this example, the light source 40E is disposed on the +x direction side with respect to the light source 40F.

In addition, although not shown, in Exemplary Embodiment 3, the irradiation region which is irradiated with the light from the light source 40E and the irradiation region which is irradiated with the light from the light source 40F are parallel to each other in the x direction on the irradiation surface 100 (see FIG. 2). More specifically, on the irradiation surface 100, the irradiation region which is irradiated with the light from the light source 40E is parallel to the irradiation region which is irradiated with the light from the light source 40F on the +x direction side.

In addition, the light emission drive unit 6 includes a driver 61 that drives the light emitting element array 41 of the light source 40E, a driver 62 that drives the light emitting element array 41 of the light source 40F, and a fan-out buffer 67 that distributes a drive signal from the control unit 8 (see FIG. 1) to the driver 61 and the driver 62. Further, the light emission drive unit 6 includes a signal line 68E that transmits the drive signal distributed by the fan-out buffer 67 to the driver 61, and a signal line 68F that transmits the drive signal to the driver 62.

As shown in FIG. 8, the driver 61 and the driver 62 are disposed at positions other than a region between the light emitting element array 41 of the light source 40E and the light emitting element array 41 of the light source 40F that are parallel to each other in the x direction.

Specifically, the driver 61 is disposed on a side opposite to the light emitting element array 41 of the light source 40F with respect to the light emitting element array 41 of the light source 40E in the x direction. It should be noted that the driver 61 is disposed on the +x direction side with respect to the light source 40E.

In addition, the driver 62 is disposed on a side opposite to the light emitting element array 41 of the light source 40E with respect to the light emitting element array 41 of the light source 40F in the x direction. It should be noted that the driver 62 is disposed on the −x direction side with respect to the light source 40F.

In this example, the light emitting element array 41 of the light source 40E is an example of a first light emitting element array, and the light emitting element array 41 of the light source 40F is an example of a second light emitting element array. In addition, the driver 61 is an example of a first driver, and the driver 62 is an example of a second driver.

In the present exemplary embodiment, the driver 61 and the driver 62 are disposed at positions other than the region between the light emitting element array 41 of the light source 40E and the light emitting element array 41 of the light source 40F, so that the light emitting element array 41 of the light source 40E and the light emitting element array 41 of the light source 40F can be disposed to be close to each other.

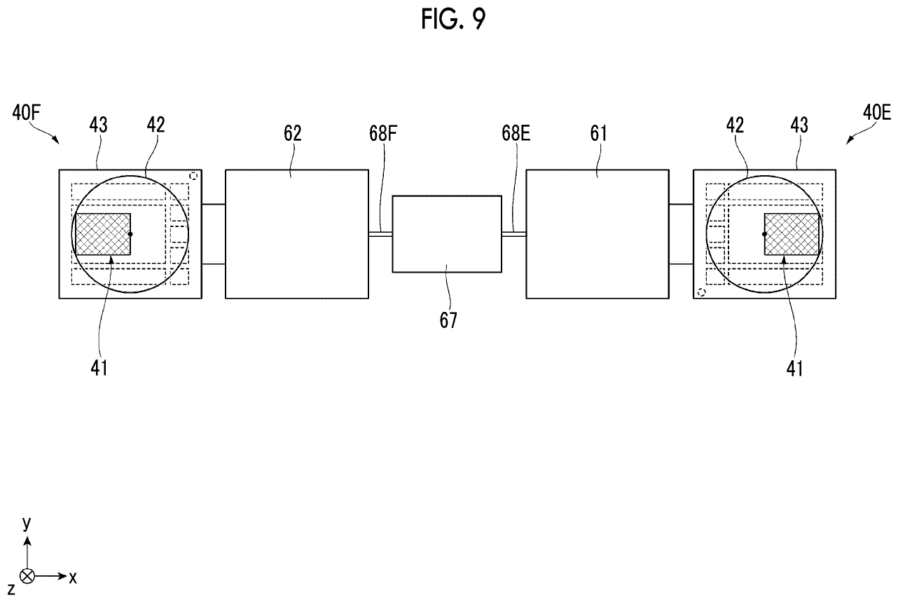

FIG. 9 is a diagram showing a comparative example of arrangement of the drivers 61 and 62, and is a view of the light emitting unit 4, and the drivers 61 and 62 and the fan-out buffer 67 constituting the light emission drive unit 6 as viewed in the +z direction from the −z direction side.

In the comparative example shown in FIG. 9, the driver 61 and the driver 62 are disposed between the light emitting element array 41 of the light source 40E and the light emitting element array 41 of the light source 40F. In this case, the distance in the x direction between the light emitting element array 41 of the light source 40E and the light emitting element array 41 of the light source 40F is increased by the width of the driver 61 and the driver 62 in the x direction.

Here, in a case where a plurality of light sources each having the light emitting element array 41 irradiate the irradiation surface 100 (see FIG. 2) with light beams, in a case where the light emitting element arrays 41 are separated from each other, a non-irradiation portion which is not irradiated with the light beams is likely to be formed between the irradiation regions which are irradiated with the light beams from the respective light sources on the irradiation surface 100 close to the light emitting unit 4 in the +z direction.

On the other hand, in the present exemplary embodiment, the driver 61 and the driver 62 are disposed at positions other than the region between the light emitting element array 41 of the light source 40E and the light emitting element array 41 of the light source 40F, so that the non-irradiation portion is less likely to be formed on the irradiation surface 100 close to the light emitting unit 4 in the +z direction.

In addition, in the present exemplary embodiment, as shown in FIG. 8, the fan-out buffer 67 is disposed at a position shifted to the −y direction side with respect to the light source 40E and the light source 40F.

In addition, the fan-out buffer 67 is disposed at an intermediate position between the light source 40E and the light source 40F in the x direction. As a result, lengths of the signal line 68E and the signal line 68F are equal to each other.

In the present exemplary embodiment, since the lengths of the signal line 68E and the signal line 68F are equal to each other, a deviation between a time required for the drive signal from the control unit 8 to reach the driver 61 via the fan-out buffer 67 and a time required for the drive signal to reach the driver 62 via the fan-out buffer 67 is less likely to occur. As a result, the light emitting element array 41 of the light source 40E and the light emitting element array 41 of the light source 40F can be accurately caused to emit light by the driver 61 and the driver 62.

Subsequently, the arrangement of drivers (drivers 63 to 66 described below) and a fan-out buffer 67 in a case where the light emitting unit 4 has four light sources 40A, 40B, 40C, and 40D will be described.

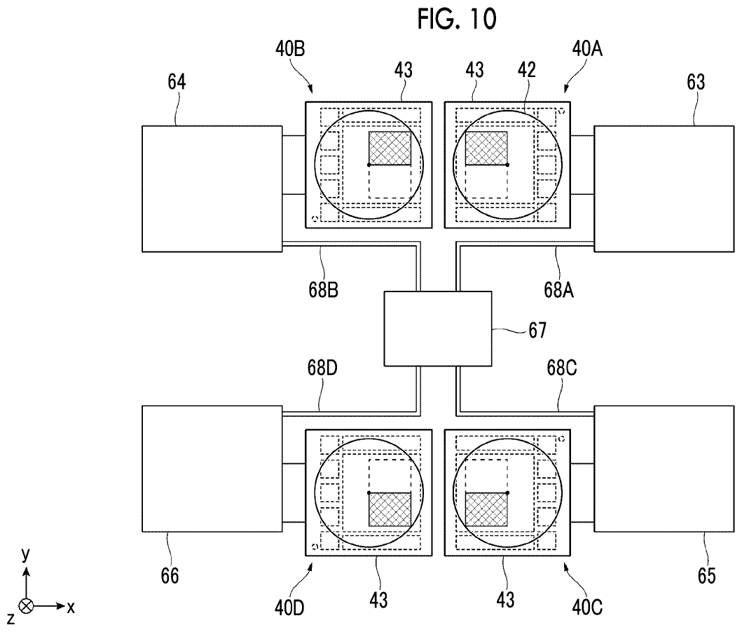

FIG. 10 is a diagram showing an example of configurations of the light emitting unit 4 and the light emission drive unit 6 in a case where the light emitting unit 4 has four light sources 40A, 40B, 40C, and 40D. FIG. 10 is a view of the light emitting unit 4, and drivers 63 to 66 and a fan-out buffer 67 constituting the light emission drive unit 6 as viewed in the +z direction from the −z direction side.

In the light emitting unit 4 shown in FIG. 10, the light source 40A and the light source 40B are disposed to be parallel to each other in the x direction, the light source 40C and the light source 40D are disposed to be parallel to each other in the x direction, the light source 40A and the light source 40C are disposed to be parallel to each other in the y direction, and the light source 40B and the light source 40D are disposed to be parallel to each other in the y direction. In this example, the light source 40A is disposed on the +x direction side with respect to the light source 40B and is disposed on the +y direction side with respect to the light source 40C. The light source 40B is disposed on the −x direction side with respect to the light source 40A and is disposed on the +y direction side with respect to the light source 40D. The light source 40C is disposed on the −y direction side with respect to the light source 40A and is disposed on the +x direction side with respect to the light source 40D. The light source 40D is disposed on the −y direction side with respect to the light source 40B and is disposed on the −x direction side with respect to the light source 40C.

In addition, the light emission drive unit 6 includes a driver 63 that drives the light emitting element array 41 of the light source 40A, a driver 64 that drives the light emitting element array 41 of the light source 40B, a driver 65 that drives the light emitting element array 41 of the light source 40C, and a driver 66 that drives the light emitting element array 41 of the light source 40D. Further, the light emission drive unit 6 includes a fan-out buffer 67 that distributes a drive signal from the control unit 8 (see FIG. 1) to the driver 63, the driver 64, the driver 65, and the driver 66. Further, the light emission drive unit 6 includes a signal line 68A that transmits the drive signal distributed by the fan-out buffer 67 to the driver 63, a signal line 68B that transmits the drive signal to the driver 64, a signal line 68C that transmits the drive signal to the driver 65, and a signal line 68D that transmits the drive signal to the driver 66.

As shown in FIG. 10, the driver 63 and the driver 64 are disposed at positions other than a region between the light emitting element array 41 of the light source 40A and the light emitting element array 41 of the light source 40B that are parallel to each other in the x direction.

Specifically, the driver 63 is disposed on a side opposite to the light emitting element array 41 of the light source 40B with respect to the light emitting element array 41 of the light source 40A in the x direction. It should be noted that the driver 63 is disposed on the +x direction side with respect to the light source 40A.

In addition, the driver 64 is disposed on a side opposite to the light emitting element array 41 of the light source 40A with respect to the light emitting element array 41 of the light source 40B in the x direction. It should be noted that the driver 64 is disposed on the −x direction side with respect to the light source 40B.

In the present exemplary embodiment, the driver 63 and the driver 64 are disposed at positions other than the region between the light emitting element array 41 of the light source 40A and the light emitting element array 41 of the light source 40B, so that the light emitting element array 41 of the light source 40A and the light emitting element array 41 of the light source 40B can be disposed to be close to each other.

In addition, as shown in FIG. 10, the driver 65 and the driver 66 are disposed at positions other than a region between the light emitting element array 41 of the light source 40C and the light emitting element array 41 of the light source 40D that are parallel to each other in the x direction.

Specifically, the driver 66 is disposed on a side opposite to the light emitting element array 41 of the light source 40D with respect to the light emitting element array 41 of the light source 40C in the x direction. It should be noted that the driver 65 is disposed on the +x direction side with respect to the light source 40C.

In addition, the driver 66 is disposed on a side opposite to the light emitting element array 41 of the light source 40C with respect to the light emitting element array 41 of the light source 40D in the x direction. It should be noted that the driver 66 is disposed on the −x direction side with respect to the light source 40D.

In the present exemplary embodiment, the driver 65 and the driver 66 are disposed at positions other than the region between the light emitting element array 41 of the light source 40C and the light emitting element array 41 of the light source 40D, so that the light emitting element array 41 of the light source 40C and the light emitting element array 41 of the light source 40D can be disposed to be close to each other.

In addition, in the present exemplary embodiment, as shown in FIG. 10, the fan-out buffer 67 is disposed at a position shifted in the y direction with respect to the light sources 40A, 40B, 40C, and 40D. Specifically, the fan-out buffer 67 is disposed between the light sources 40A and 40B and the light sources 40C and 40D. It should be noted that the fan-out buffer 67 is disposed at an intermediate position between the light sources 40A and 40B and the light sources 40C and 40D in the y direction.

In addition, the fan-out buffer 67 is disposed at an intermediate position between the driver 63 that drives the light source 40A and the driver 64 that drives the light source 40B in the x direction, and at an intermediate position between the driver 65 that drives the light source 40C and the driver 66 that drives the light source 40D.

As a result, in the example shown in FIG. 10, lengths of the signal lines 68A, 68B, 68C, and 68D are equal to each other.

In the present exemplary embodiment, since the lengths of the signal lines 68A, 68B, 68C, and 68D are equal to each other, a time required for the drive signal from the control unit 8 to reach the drivers 63 to 66 via the fan-out buffer 67 is less likely to be deviated. As a result, the light emitting element array 41 of the light source 40A, the light emitting element array 41 of the light source 40B, the light emitting element array 41 of the light source 40C, and the light emitting element array 41 of the light source 40D can be accurately caused to emit by the drivers 63 to 66.

Although the exemplary embodiments of the present invention have been described above, a technical scope of the present invention is not limited to the scope described in the above-mentioned exemplary embodiments.

For example, in the above-described exemplary embodiments, in the light emitting unit 4, the lens 42 that refracts the light emitted from the light emitting element array 41 has been described as an example of the optical system, but the optical system is not limited to the lens 42 as long as the optical system refracts the light emitted from the light emitting element array 41 to expand the irradiation region of the light. As the optical system, for example, a diffractive optical element (DOE) that changes an angle of incident light and emits the light may be used.

In addition, it is apparent from claims that exemplary embodiments in which various modifications or improvements are added to the above-mentioned exemplary embodiments are also included in the technical scope of the present invention.

### Supplementary Note

(((1)))

Alight emitting device comprising:
a light emitting element array in which a plurality of light emitting elements are arranged such that a length in one direction is w, the light emitting element array being a first light emitting element array and a second light emitting element array that are parallel to each other in the one direction;
a first optical system that refracts light emitted from the first light emitting element array; and
a second optical system that refracts light emitted from the second light emitting element array such that an irradiation region of the second light emitting element array is parallel to an irradiation region of the first light emitting element array in the one direction,
wherein a distance between an optical axis of the first optical system and a center of the first light emitting element array and a distance between an optical axis of the second optical system and a center of the second light emitting element array in the one direction are w/4 or more and w/2 or less.

(((2)))

The light emitting device according to (((1))), further comprising:
a third light emitting element array that is parallel to the first light emitting element array in another direction intersecting the one direction; and
a third optical system that refracts light emitted from the third light emitting element array such that an irradiation region of the third light emitting element array is parallel to the irradiation region of the first light emitting element array in the other direction,
wherein, in the first light emitting element array and the third light emitting element array, the plurality of light emitting elements are arranged such that a length in the other direction is h, and
a distance between the optical axis of the first optical system and the center of the first light emitting element array and a distance between an optical axis of the third optical system and a center of the third light emitting element array in the other direction are h/4 or more and h/2 or less.

(((3)))

The light emitting device according to (((2))),
wherein the light emitting element array has a rectangular shape in which a length of a side in the one direction is w and a length of a side in the other direction is h, and
the optical axis of the optical system is located on any one diagonal line of the rectangular shape.

(((4)))

The light emitting device according to (((3))),
wherein the optical axis of the optical system passes through any one vertex of the rectangular shape.

(((5)))

The light emitting device according to any one of (((1))) to (((4))),
wherein the first light emitting element array and the first optical system are fixed on a first sub-mount substrate,
the second light emitting element array and the second optical system are fixed on a second sub-mount substrate, and
the first sub-mount substrate and the second sub-mount substrate are disposed such that the first light emitting element array and the second light emitting element array are parallel to each other in the one direction.

(((6)))

The light emitting device according to (((5))),
wherein the first light emitting element array and the second light emitting element array are configured by a common light emitting element array,
the first optical system and the second optical system are configured by a common optical system, and
the light emitting element array and the optical system are fixed to the sub-mount substrate such that a distance between the first light emitting element array and the first optical system and a distance between the second light emitting element array and the second optical system are equal.

(((7)))

The light emitting device according to any one of (((1))) to (((6))), further comprising:
a fourth light emitting element array that is parallel to the first light emitting element array in the one direction and another direction intersecting the one direction; and
a fourth optical system that refracts light emitted from the fourth light emitting element array such that an irradiation region of the fourth light emitting element array is parallel to the irradiation region of the first light emitting element array,
wherein the first light emitting element array and the fourth light emitting element array have a two-fold symmetric or four-fold symmetric shape, and
a combination of the fourth light emitting element array and the fourth optical system has a configuration in which a combination of the first light emitting element array and the first optical system is rotated by 180 degrees around the optical axis of the first optical system.

(((8)))

The light emitting device according to (((7))),
wherein the first light emitting element array, the second light emitting element array, and the fourth light emitting element array have a four-fold symmetric shape, and
a combination of the second light emitting element array and the second optical system has a configuration in which the combination of the first light emitting element array and the first optical system is rotated by 90 degrees around the optical axis of the first optical system.

(((9)))

The light emitting device according to any one of (((1))) to (((8))), further comprising:
a first driver that drives the first light emitting element array; and
a second driver that drives the second light emitting element array,
wherein the first driver and the second driver are disposed at positions other than a region between the first light emitting element array and the second light emitting element array.

(((10)))

The light emitting device according to any one of (((1))) to (((9))),
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1).

$$R \geq 2 \times \sqrt{{w}^{2} + {( \frac{nh}{2} )}^{2}} \qquad ( 1 )$$

(((11)))

A distance measurement apparatus comprising:
the light emitting device according to any one of (((1))) to (((10)));
a light receiving unit that receives light emitted from the light emitting device and reflected by a target object; and
a calculation unit that calculates a distance to the target object based on a result of the light reception in the light receiving unit.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a light emitting element array in which a plurality of light emitting elements are arranged such that a length in one direction is w, the light emitting element array being a first light emitting element array and a second light emitting element array that are parallel to each other in the one direction;
a first optical system that refracts light emitted from the first light emitting element array; and
a second optical system that refracts light emitted from the second light emitting element array such that an irradiation region of the second light emitting element array is parallel to an irradiation region of the first light emitting element array in the one direction,
wherein a distance between an optical axis of the first optical system and a center of the first light emitting element array and a distance between an optical axis of the second optical system and a center of the second light emitting element array in the one direction are w/4 or more and w/2 or less.

2. The light emitting device according to claim 1, further comprising:
a third light emitting element array that is parallel to the first light emitting element array in another direction intersecting the one direction; and
a third optical system that refracts light emitted from the third light emitting element array such that an irradiation region of the third light emitting element array is parallel to the irradiation region of the first light emitting element array in the other direction,
wherein, in the first light emitting element array and the third light emitting element array, the plurality of light emitting elements are arranged such that a length in the other direction is h, and
a distance between the optical axis of the first optical system and the center of the first light emitting element array and a distance between an optical axis of the third optical system and a center of the third light emitting element array in the other direction are h/4 or more and h/2 or less.

3. The light emitting device according to claim 2,
wherein the light emitting element array has a rectangular shape in which a length of a side in the one direction is w and a length of a side in the other direction is h, and
the optical axis of the optical system is located on any one diagonal line of the rectangular shape.

4. The light emitting device according to claim 3,
wherein the optical axis of the optical system passes through any one vertex of the rectangular shape.

5. The light emitting device according to claim 1,
wherein the first light emitting element array and the first optical system are fixed on a first sub-mount substrate,
the second light emitting element array and the second optical system are fixed on a second sub-mount substrate, and
the first sub-mount substrate and the second sub-mount substrate are disposed such that the first light emitting element array and the second light emitting element array are parallel to each other in the one direction.

6. The light emitting device according to claim 5,
wherein the first light emitting element array and the second light emitting element array are configured by a common light emitting element array,
the first optical system and the second optical system are configured by a common optical system, and
the light emitting element array and the optical system are fixed to the sub-mount substrate such that a distance between the first light emitting element array and the first optical system and a distance between the second light emitting element array and the second optical system are equal.

7. The light emitting device according to claim 1, further comprising:
a fourth light emitting element array that is parallel to the first light emitting element array in the one direction and another direction intersecting the one direction; and
a fourth optical system that refracts light emitted from the fourth light emitting element array such that an irradiation region of the fourth light emitting element array is parallel to the irradiation region of the first light emitting element array,
wherein the first light emitting element array and the fourth light emitting element array have a two-fold symmetric or four-fold symmetric shape, and
a combination of the fourth light emitting element array and the fourth optical system has a configuration in which a combination of the first light emitting element array and the first optical system is rotated by 180 degrees around the optical axis of the first optical system.

8. The light emitting device according to claim 7,
wherein the first light emitting element array, the second light emitting element array, and the fourth light emitting element array have a four-fold symmetric shape, and
a combination of the second light emitting element array and the second optical system has a configuration in which the combination of the first light emitting element array and the first optical system is rotated by 90 degrees around the optical axis of the first optical system.

9. The light emitting device according to claim 1, further comprising:
a first driver that drives the first light emitting element array; and
a second driver that drives the second light emitting element array,
wherein the first driver and the second driver are disposed at positions other than a region between the first light emitting element array and the second light emitting element array.

10. The light emitting device according to claim 1,
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

11. The light emitting device according to claim 2,
wherein the light emitting element array has a rectangular shape in which a length of a side in the one direction is w and a length of a side in the other direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

12. The light emitting device according to claim 3,
wherein the light emitting element array has a rectangular shape in which a length of a side in the one direction is w and a length of a side in the other direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

13. The light emitting device according to claim 4,
wherein the light emitting element array has a rectangular shape in which a length of a side in the one direction is w and a length of a side in the other direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

14. The light emitting device according to claim 5,
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1)×
$$R \geq 2 \times \sqrt{{w}^{2} + {( \frac{nh}{2} )}^{2}} \qquad ( 1 )$$

15. The light emitting device according to claim 6,
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

16. The light emitting device according to claim 7,
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

17. The light emitting device according to claim 8,
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

18. The light emitting device according to claim 9,
wherein the light emitting element array has a rectangular shape in which a length of a side in the one direction is w and a length of a side in another direction intersecting the one direction is h,
n (n is a natural number of 1 or more) light emitting element arrays including the first light emitting element array are parallel to each other in the other direction, and
an effective diameter R of the optical system is set to satisfy Equation (1)
$$R \geq 2 \times \sqrt{{w}^{2} + {( \frac{nh}{2} )}^{2}} \qquad ( 1 )$$

19. A distance measurement apparatus comprising:
the light emitting device according to claim 1;
a light receiving unit that receives light emitted from the light emitting device and reflected by a target object; and
a calculation unit that calculates a distance to the target object based on a result of the light reception in the light receiving unit.

20. A distance measurement apparatus comprising:
the light emitting device according to claim 2;
a light receiving unit that receives light emitted from the light emitting device and reflected by a target object; and
a calculation unit that calculates a distance to the target object based on a result of the light reception in the light receiving unit.
